(19) United States
(12) Patent Application Publication
(10) Pub. No.: US 2024/0154008 A1
(43) Pub. Date: May 9, 2024

(54) SEMICONDUCTOR DEVICE

(71) Applicant: Industrial Technology Research Institute, Hsinchu (TW)

(72) Inventors: Chih-Hung Yen, Taipei City (TW); Yu-Ting Chen, Hsinchu County (TW); Hua-Mao Chen, Tainan City (TW)

(73) Assignee: Industrial Technology Research Institute, Hsinchu (TW)

(21) Appl. No.: 18/151,487

(22) Filed: Jan. 9, 2023

(30) Foreign Application Priority Data
Nov. 8, 2022 (TW) 111142548

(51) Int. Cl. H01L 29/40; H01L 29/16; H01L 29/66; H01L 29/78

(52) U.S. Cl. CPC H01L 29/408; H01L 29/1608; H01L 29/66068; H01L 29/7813

(57) ABSTRACT

Provided is a semiconductor device including a substrate, a channel layer, a gate structure, a first doped region, a second doped region, a third doped region and a channel cap layer. The channel layer is located on the substrate. The channel layer has a trench. The gate structure is disposed in the trench. The first doped region and the second doped region are located in the channel layer on two sides of the gate structure. The third doped region is located in the substrate below the channel layer. The channel cap layer is located between the gate structure and the first doped region, between the gate structure and the second doped region, and between the gate structure and the channel layer. An energy band gap of the channel cap layer is larger than an energy band gap of the channel layer.

### CROSS-REFERENCE TO RELATED APPLICATION

This application claims the priority benefit of Taiwanese application no. 111142548, filed on Nov. 8, 2022. The entirety of the above-mentioned patent application is hereby incorporated by reference herein and made a part of this specification.

### TECHNICAL FIELD

The disclosure relates to an integrated circuit, and particularly relates to a semiconductor device.

### BACKGROUND

In a semiconductor device, a gate structure is disposed on a channel layer and in direct contact with a gate dielectric layer. However, due to a lattice mismatch between a gate dielectric material and a channel material, a large amount of defective charges, such as dangling bonds, carbon clusters, or oxygen vacancies, may be present at the interface. As a result, the carrier mobility of the channel may be low, and the device properties of threshold voltage, resistance, and output current, etc., may be affected.

### SUMMARY

Some embodiments of the disclosure provides a semiconductor device including a substrate, a channel layer, a gate structure, a first doped region, a second doped region, a third doped region, and a channel cap layer. The channel layer is located on the substrate. The channel layer has a trench. The gate structure is disposed in the trench. The first doped region and the second doped region are located in the channel layer on two sides of the gate structure. The third doped region is located in the substrate below the channel layer. The channel cap layer is located between the gate structure and the first doped region, between the gate structure and the second doped region, and between the gate structure and the channel layer. An energy band gap of the channel cap layer is larger than an energy band gap of the channel layer.

Some other embodiments of the disclosure provides a semiconductor device including a substrate, a channel layer, a gate structure, a first doped region, a second doped region, a third doped region, and a channel cap layer. The channel layer is located on the substrate. The gate structure is disposed above the channel layer. The first doped region and the second doped region are located in the channel layer on two sides of the gate structure. The third doped region is located in the substrate below the channel layer. The channel cap layer is located between the gate structure and the channel layer. An energy band gap of the channel cap layer is larger than an energy band gap of the channel layer.

Yet some other embodiments of the disclosure provides a semiconductor device including a substrate, a fin, a channel layer, a gate structure, a first doped region, a second doped region, and a channel cap layer. The fin is located on the substrate and protrudes from a surface of the substrate. The channel cap layer covers the substrate and a top surface and sidewalls of the fin. The gate structure is located on the channel cap layer above the substrate. The channel layer is located in the fin. The first doped region is located in the channel layer. The second doped region is located in the substrate below the channel layer. The channel cap layer is located between the gate structure and the first doped region and between the gate structure and the channel layer. An energy band gap of the channel cap layer is larger than an energy band gap of the channel layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1F are schematic cross-sectional views illustrating a manufacturing process of a semiconductor device according to some embodiments of the disclosure.

FIGS. 2A to 2G are schematic cross-sectional views illustrating a manufacturing process of a semiconductor device according to some other embodiments of the disclosure.

FIGS. 3A to 3E are schematic cross-sectional views illustrating a manufacturing process of a semiconductor device according to still some other embodiments of the disclosure.

FIGS. 4A to 4F are schematic cross-sectional views illustrating a manufacturing process of a semiconductor device according to yet some other embodiments of the disclosure.

### DETAILED DESCRIPTION OF DISCLOSED EMBODIMENTS

In semiconductor materials, some compound materials, such as silicon carbide (SiC), exhibit a high breakdown voltage (approximately 10 times of silicon (Si)) and high thermal conductivity (approximately 3 times of Si), and are therefore suitable for application in a high power device. In addition, SiC materials exhibit an electron carrier mobility as high as 1000 cm/V·s. A silicon oxide gate dielectric layer for a silicon carbide (SiC) MOSFET is conventionally formed by performing a thermal oxidation process. However, due to lattice mismatch between silicon oxide and silicon carbide, a large amount of defective charges, such as dangling bonds, carbon clusters, or oxygen vacancies, may be present at the interface thereof. As a result, the carrier mobility of the channel may be low (<20 cm/V·s), and the properties of device starting, voltage resistance, and current output, etc., may be affected.

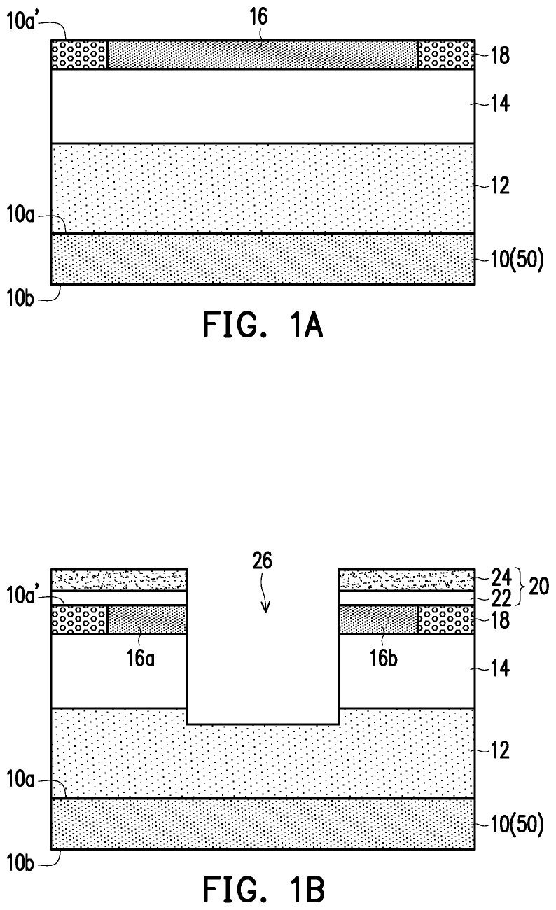

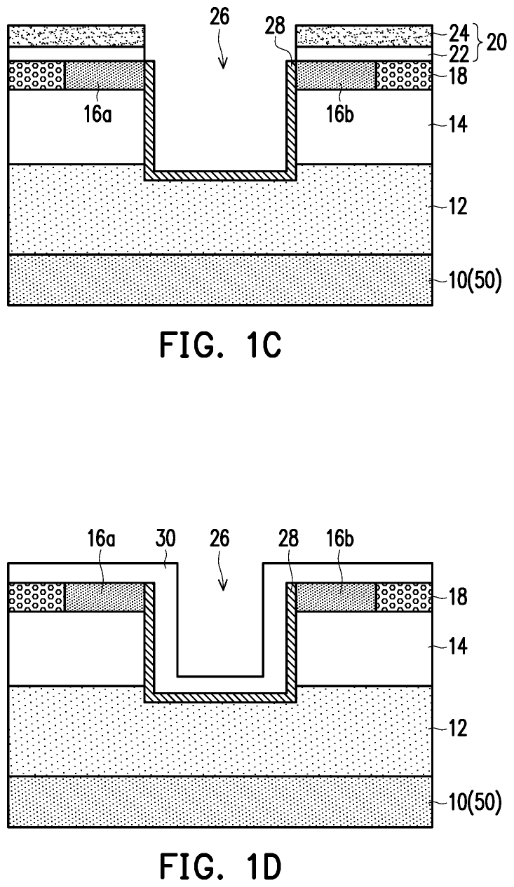

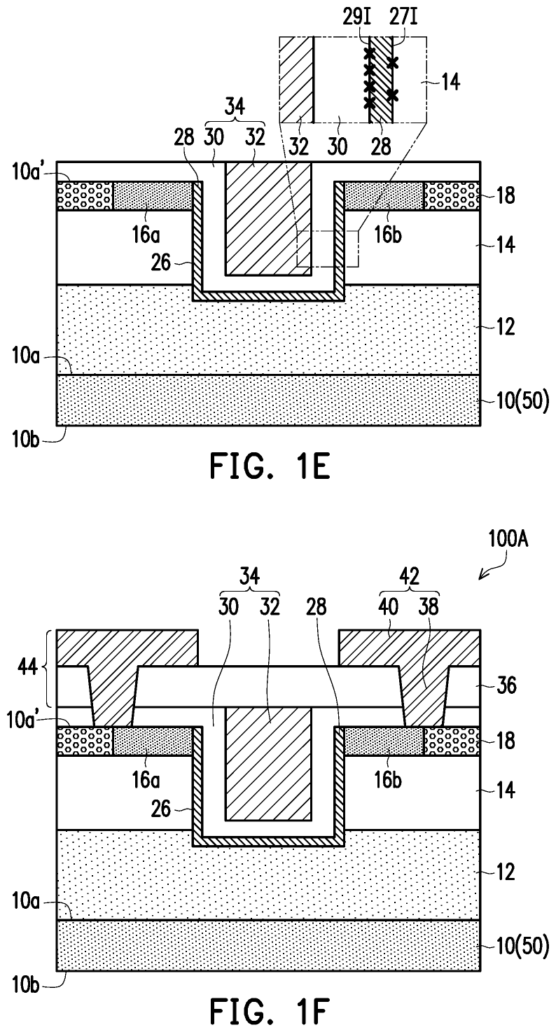

According to some embodiments of the disclosure, a channel cap layer is provided between a gate dielectric layer of a gate structure and a channel layer. The energy band gap of the channel cap layer is greater than the energy band gap of the channel layer. Therefore, carriers are mainly transmitted in the channel layer, thus rendering a buried channel effect. Therefore, in some embodiments of the disclosure, by disposing the channel cap layer, carriers could be prevented from being trapped by defects at the interface between the gate dielectric layer and the channel layer in direct contact. As a result, carrier mobility is facilitated. In the following, semiconductor devices 100A to 100D and manufacturing methods thereof are described. The semiconductor devices 100A to 100D are, for example, high-power devices, as shown in FIGS. 1F, 2G, 3E, and 4F.

Referring to FIG. 1F, the semiconductor device 100A of the disclosure includes a substrate 10, a channel layer 14, a gate structure 34, a first doped region 16a, a second doped region 16b, a third doped region 50, and a channel cap layer 28. In some embodiments, the semiconductor device 100A further includes a buffer layer 12. In some other embodiments, the semiconductor device 100A further includes a doped region 18 and a metal interconnect structure 44.

In some embodiments, the substrate 10 has a first surface 10a and a second surface 10b. The buffer layer 12 and the channel layer 14 are formed above the first surface 10a of the substrate 10. The buffer layer 12 is provided between the channel layer 14 and the substrate 10. In some other embodiments, the substrate 10 has a first surface 10a′ and the second surface 10b. The buffer layer 12 and the channel layer 14 are formed in the substrate 10. The channel layer 14 extends from the first surface 10a′ to the second surface 10b. The buffer layer 12 is formed below the channel layer 14.

The channel layer 14 has a trench 26. A bottom surface of the trench 26 extends to the buffer layer 12. The gate structure 34 is disposed in the trench 26. The first doped region 16a and the second doped region 16b are located in the channel layer 14 on two sides of the gate structure 34. The third doped region 50 is located in the substrate 10 below the buffer layer 12. The channel cap layer 28 is located between the gate structure 34 and the first doped region 16a, between the gate structure 34 and the second doped region 16b, and between the gate structure 34 and the buffer layer 12. An energy band gap of the channel cap layer 28 is larger than an energy band gap of the channel layer 14.

In some embodiments, the semiconductor device 100A of the disclosure may be formed in accordance with a manufacturing method described in the following. However, the disclosure is not limited thereto. FIGS. 1A to 1F are schematic cross-sectional views illustrating a manufacturing process of the semiconductor device 100A according to some embodiments of the disclosure.

Referring to FIG. 1A, the material of the substrate 10 include a semiconductor or a semiconductor compound, such as silicon carbide (SiC), silicon (Si), gallium nitride (GaN), or sapphire. The third doped region 50 is formed in the substrate 10. The third doped region 50 extends from the second surface 10b of the substrate 10 toward the first surface 10a (or the first surface 10a′). The third doped region 50, for example, has a second conductivity type dopant. The second conductivity type dopant is, for example, an N-type dopant, such as phosphorus (P) or arsenic (As). The third doped region 50 may be formed in situ by performing an ion implantation process or during an epitaxial growth process for forming the substrate 10.

Referring to FIG. 1A, a process for forming the buffer layer 12 and the channel layer 14 is performed. In some embodiments, the buffer layer 12 and the channel layer 14 are formed above the first surface 10a of the substrate 10 by performing an epitaxial growth process. In some other embodiments, the buffer layer 12 and the channel layer 14 are formed by forming a well region or a doped region by implanting a dopant into the substrate 10 from the first surface 10a′ of the substrate 10 through an ion implantation process.

The material of the buffer layer 12 includes a semiconductor. The semiconductor may be a semiconductor element or a semiconductor compound, such as silicon carbide (SiC), silicon (Si), gallium nitride (GaN), or sapphire. The material of the buffer layer 12 may be the same as or different from the material of the substrate 10. The material of the channel layer 14 includes a semiconductor, such as silicon carbide (SiC), germanium (Ge), gallium nitride (GaN), gallium oxide (β-Ga₂O₃), aluminum nitride (AlN), diamond, silicon germanium (SiGe) or silicon (Si). When the material of the channel layer 14 is SiC, the material may have various crystal phases, such as 3C—SiC, 4H—SiC, or 6H—SiC. The material of the channel layer 14 may be the same as or different from the material of the substrate 10. The material of the channel layer 14 may be the same as or different from the material of the buffer layer 12. The materials of the buffer layer 12 and the channel layer 14 may be the same as the material of the substrate 10 but have a different crystal phase. For example, the substrate 10 includes SiC having a crystal plane (0001), the buffer layer 12 includes 2H—SiC, the channel layer 14 includes 3C—SiC, 4H—SiC, or 6H—SiC.

The conductivity type of the buffer layer 12 is the same as the conductivity type of the third doped region 50. The conductivity type of the channel layer 14 is different from the conductivity type of the buffer layer 12 and the third doped region 50. For example, the channel layer 14 includes a first conductivity type dopant, and the buffer layer 12 includes a second conductivity type dopant. The first conductivity type dopant is, for example, a P-type dopant, such as boron (B) or boron fluoride (BF₃). The second conductivity type dopant is, for example, an N-type dopant, such as phosphorus (P) or arsenic (As). The doped concentration of the buffer layer 12 is lower than the doped concentration of the third doped region 50. The dopant in the buffer layer 12 and the channel layer 14 may be formed in situ during an epitaxial growth process, or is formed by forming a well region or a doped region by implanting a dopant in the substrate 10 through an ion implantation process.

Then, a doped region 16 and a doped region 18 of different conductivity types are formed in the channel layer 14. The conductivity type of the doped region 16 is different from the conductivity type of the channel layer 14. The conductivity type of the doped region 18 is the same as the conductivity type of the channel layer 14. The doped region 16, for example, has a second conductivity type dopant. The doped region 18, for example, has a first conductivity type dopant. The second conductivity type dopant is, for example, an N-type dopant, such as phosphorus (P) or arsenic (As). The doped region 16 and the doped region 18 may each be formed by forming a patterned photoresist layer above the substrate 10 by performing a photolithography process and performing an ion implantation process by using the patterned photoresist layer as a mask.

Referring to FIG. 1B, subsequently, a mask layer 20 is formed on the channel layer 14. The mask layer 20 may include a silicon oxide layer 22 and a silicon nitride layer 24. The silicon nitride layer 24 is formed on the silicon oxide layer 22. The mask layer 20 may be patterned by performing a photolithography process and an etching process. Then, by using the mask layer 20 as a mask, an etching process is performed to form the trench 26 in the channel layer 14. The trench 26 extends and passes through the channel layer 14. In some embodiments, the bottom part of the trench 26 extends to the channel layer 14. After the trench 26 is formed, the doped region 16 is divided into the first doped region 16a and the second doped region 16b. The doped region 18 is adjacent to the first doped region 16a and the second doped region 16b.

Referring to FIG. 1C, in an embodiment of the disclosure, the channel cap layer 28 is formed before the gate structure 34 (shown in FIG. 1E) is formed in the trench 26. In an embodiment of the disclosure, the channel cap layer 28 is formed on the sidewalls and the bottom surface of the trench 26, so as to surround the sidewalls and the bottom surface of the gate structure 34 formed subsequently. In other words, the material and the function of the channel cap layer 28 will be described in detail subsequently.

Referring to FIG. 1D, the mask layer 20 is removed. Then, the gate structure 34 is formed in the trench 26. The gate structure 34 includes a gate dielectric layer 30 and a gate conductor layer 32.

The material of the gate dielectric layer 30 may include, for example, silicon oxide (SiO₂), silicon oxynitride (SiON), silicon nitride (SiN), a high-k dielectric material layer, such as aluminum oxide (Al₂O₃), hafnium oxide (HfO₂), zirconium dioxide (ZrO₂), or a combination thereof. The material of the gate conductor layer 32 may include polysilicon, titanium (Ti), aluminum (Al), tungsten (W), aurum (Au), or a combination thereof. Processes for forming the gate dielectric layer 30 and the gate conductor layer 32 may include steps as follows. Firstly, a gate dielectric material and a gate conductor material are formed on the channel layer 14. Then, the gate conductor material except for the trench 26 is removed by performing an etching back process or a chemical mechanical polishing process. The gate conductor layer 32 is located in the trench 26. The gate dielectric layer 30 may be a conformal layer and cover the sidewalls and the bottom surface of the gate conductor layer 32. The gate dielectric layer 30 may also extend and cover the first doped region 16a, the second doped region 16b, and the doped region 18.

Referring to FIG. 1F, the metal interconnect structure 44 is formed above the channel layer 14. The metal interconnect structure 44 includes a dielectric layer 36 and a metal interconnect 42. The metal interconnect 42 includes a contact via 38 and a conductive wire 40. The contact via 38 extends and passes through the dielectric layer 36 to be respectively electrically connected with the first doped region 16a and the doped region 18 and electrically connected with the second doped region 16b and the doped region 18. The conductive wire 40 is located on the dielectric layer 36 and electrically connected with the contact via 38. The metal interconnect structure 44 may be formed by adopting any conventional process. Therefore, details in this regard will not be repeated in the following.

Referring to FIGS. 1E and 1F, it is known that, if the channel cap layer 28 according to the embodiments of the disclosure is absent, the channel layer 14 may be brought into direct contact with the gate dielectric layer 30. When the difference between the lattice constant of the channel layer 14 and the lattice constant of the gate dielectric layer 30 is too large, that is, when a lattice mismatch rate is too large, the reliability and the service time of the semiconductor device 100A may be affected. The lattice mismatch rate described herein is defined in the following:

R=|(L_{C}−L_{D})|*100/L_{D}
wherein,
R: Lattice mismatch rate;
L_{C}: Lattice constant of channel layer;
L_{D}: Lattice constant of gate dielectric layer.

For example, when the gate dielectric layer 30 includes silicon oxide and the channel layer 14 includes silicon, L_{D} is 5.59 Å, L_{C} is 5.43 Å, and R is −2.86. The lattice mismatch rate between silicon oxide and silicon is low. However, when the gate dielectric layer 30 includes silicon oxide and the channel layer 14 includes 4H—SiC, L_{D} is 5.59 Å, L_{C} is 3.08 Å, and R is −44.9. The lattice mismatch rate between silicon oxide and silicon carbide becomes high. The lattice mismatch between the channel layer 14 and the gate dielectric layer 30 may easily lead to a defect at the interface thereof. A carrier may be trapped by the defect and, as a result, carrier mobility is reduced.

In the embodiment, particularly when the lattice mismatch rate is greater than 10%, the carrier channel may be configured to be away from the gate dielectric layer 30 by disposing the channel cap layer 28 according to the embodiments of the disclosure, and the chance that a carrier is trapped by the defect of the gate dielectric layer 30 is reduced. As a result, the characteristic shift of the semiconductor device 100A after operation for a long time could be reduced, and the reliability and the service time of the semiconductor device 100A could be facilitated.

The channel cap layer 28 and the gate conductor layer 32 sandwich the gate dielectric layer 30. More specifically, the channel cap layer 28 is located between the gate dielectric layer 30 and the first doped region 16a, between the gate dielectric layer 30 and the second doped region 16b, between the gate dielectric layer 30 and the channel layer 14, and between the gate dielectric layer 30 and the buffer layer 12.

The energy band gap of the channel cap layer 28 is larger than the energy band gap of the channel layer 14. In some embodiments, the difference between the energy band gap of the channel cap layer 28 and the energy band gap of the channel layer 14 is less than 1 eV. For example, with the difference between the energy band gap of the channel cap layer 28 and the energy band gap of the channel layer 14 being between 0.08 eV and 1 eV, a carrier is able to move in the channel layer 14 below the channel cap layer 28. If the difference in energy band gap is less than 0.08 eV, due to a thermal distribution effect, the chance that a carrier moves in the channel cap layer 28 increases. As a result, carrier mobility is reduced. If the difference in energy band gap is greater than 1 eV, the channel cap layer 28 and the channel layer 14 may strike a balance in fermi energy level. As a result, a buried channel effect is suppressed. The electron affinity of the channel layer 14 is greater than the electron affinity of the channel cap layer 28. In some embodiments, the difference between the electron affinity of the channel layer 14 and the electron affinity of the channel cap layer 28 is between 0.08 eV and 1 eV. Therefore, the carrier may move in the channel layer 14 below the channel cap layer 28. If the difference in electron affinity is less than 0.08 eV, due to a thermal distribution effect, the chance that a carrier moves in the channel cap layer 28 increases. As a result, carrier mobility is reduced. If the difference in electron affinity is greater than 1 eV, the channel cap layer 28 and the channel layer 14 may strike a balance in fermi energy level. As a result, a buried channel effect is suppressed.

The material of the channel cap layer 28 includes a semiconductor material. The material of the channel cap layer 28 may include silicon carbide (SiC), gallium nitride (GaN), aluminium gallium oxide (AlₓGa₁₋ₓO), aluminium gallium nitride (AlGaₓN₁₋ₓ), aluminium nitride (AlN), gallium oxide (β-Ga₂O₃), diamond, silicon germanium (SiGe), or silicon (Si). When the material of the channel cap layer 28 is SiC, the material may have various crystal phases, such as 2H—SiC, 4H—SiC, or 6H—SiC. In addition, the channel cap layer 28 may be a single-layer structure or a multi-layer structure. In some embodiments, the material of the channel cap layer 28 may be the same as the material of the channel layer 14 but have a different crystal phase. For example, the channel layer 14 may include 4H—SiC, and the channel cap layer 28 may include 2H—SiC. The channel layer 14 may include 6H—SiC, and the channel cap layer 28 may include 4H—SiC, 2H—SiC, or a combination thereof. The channel layer 14 may include 3H—SiC, and the channel cap layer 28 may include 6H—SiC, 4H—SiC, 2H—SiC, or a combination thereof. In some other embodiments, the material of the channel cap layer 28 may be different from the material of the channel layer. For example, the channel layer 14 may include germanium (Ge), and the channel cap layer 28 may include silicon (Si). The channel layer 14 may include gallium oxide (β-Ga₂O₃), and the channel cap layer 28 may include aluminium gallium oxide (AlₓGa₁₋ₓO), aluminium gallium nitride (AlGaₓN₁₋ₓ), or a combination thereof. The channel layer 14 may include GaN, and the channel cap layer 28 may include β-Ga₂O₃, AlₓGa₁₋ₓO, AlGaₓN₁₋ₓ, or a combination thereof. x is between 0 and 1. The channel cap layer 28 and the channel layer 14 have the same conductivity type. The channel cap layer 28, the channel layer 14, and the doped region 18 have the same conductivity type, such as the first conductivity type. The doped concentration of the channel cap layer 28 is greater than or equal to the doped concentration of the channel layer 14, and is less than the doped concentration of the doped region 18. The thickness of the channel cap layer 28 is less than 100 nm. In some embodiments, the thickness of the channel cap layer 28 ranges from 2 nm to 100 nm. If the channel cap layer 28 is less than 2 nm, the carrier channel is unable to be kept away from the gate dielectric layer 30. The drain current is positively proportional to the capacitance of the gate oxide layer. The definition of the drain current is as follows:

I_{d}=Cₒₓ*W/L*μ*(V_{gs}−Vₜₕ)*V_{ds}
wherein I_{d} represents drain current;
Cₒₓ represents gate oxide layer capacitance;
W represents channel width;
L represents channel length;
μ represents carrier mobility;
V_{gs} represents gate voltage;
Vₜₕ represents threshold voltage;
V_{ds} represents drain voltage.

The capacitance (Cₒₓ) for the gate to control the channel is the gate dielectric layer capacitance (C_{GOX}) in serial connection with the cap layer capacitance (C_{capping}), 1/Cox=1/C_{GOX}+1/C_{capping}, and C_{capping} is equal to εA/d, wherein ε represents dielectric constant, A represents area, and d represents distance. Therefore, when the thickness of the channel cap layer 28 increases, the distance d increases, and the cap layer capacitance C_{capping} decreases. As a result, the gate oxide layer capacitance Cₒₓ decreases, and, as a result, the drain current I_{d} decreases. If the thickness of the channel cap layer 28 is too thick, such as thicker than 100 nm, the drain current I_{d} is lower than the surface channel current. In such case, the output current is no longer increased.

Since the difference in lattice constant between the material of the channel layer 14 and the material of the channel cap layer 28 is smaller, the lattice mismatch rate between the channel layer 14 and the channel cap layer 28 is smaller, and the number of defects of an interface 27I is smaller. The difference in lattice constant between the material of the channel cap layer 28 and the material of the gate dielectric layer 30 is greater. Therefore, the lattice mismatch rate between the channel cap layer 28 and the gate dielectric layer 30 is greater, and the number of defects of an interface 29I is greater.

Moreover, since the energy band gap of the channel cap layer 28 is greater than the energy band gap of the channel layer 14, the majority of carriers flowing out from the first doped region 16a and the second doped region 16b flow to the third doped region 50 via the channel layer 14 with a smaller energy band gap, whereas only a small number of carriers flow via the channel cap layer 28 with a greater energy band gap to the third doped region 50. Since the carriers are able to avoid an interface 29I with a greater number of defects, the embodiments of the disclosure are able to facilitate carrier mobility and allow the carrier channel to be away from the gate dielectric layer 30 and reduce the chance that a carrier is trapped by a defect of the gate dielectric layer 30. As a result, the characteristic shift of the semiconductor device 100A after operation for a long time could be reduced, and the reliability and the service time of the semiconductor device 100A could be facilitated.

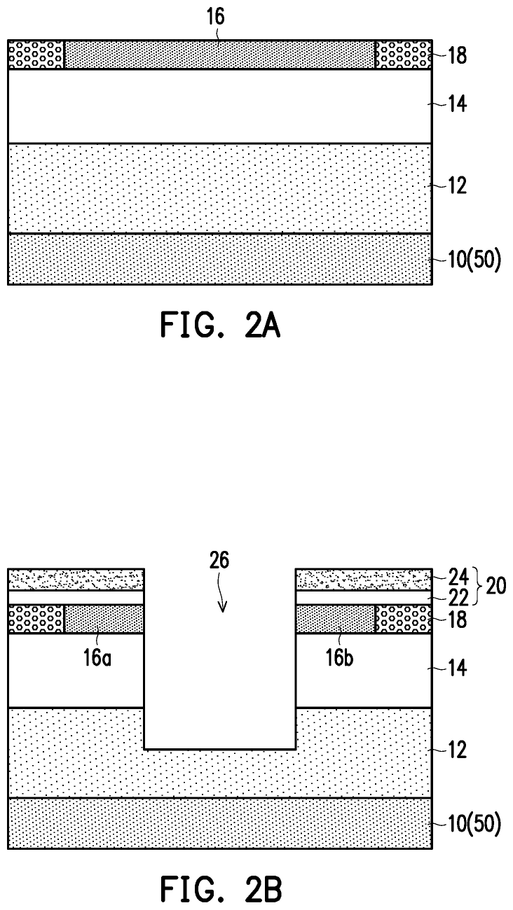

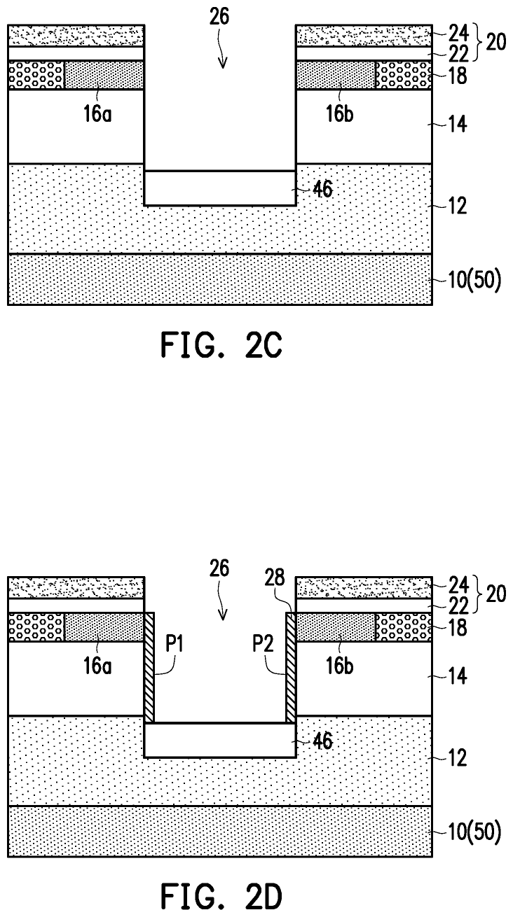

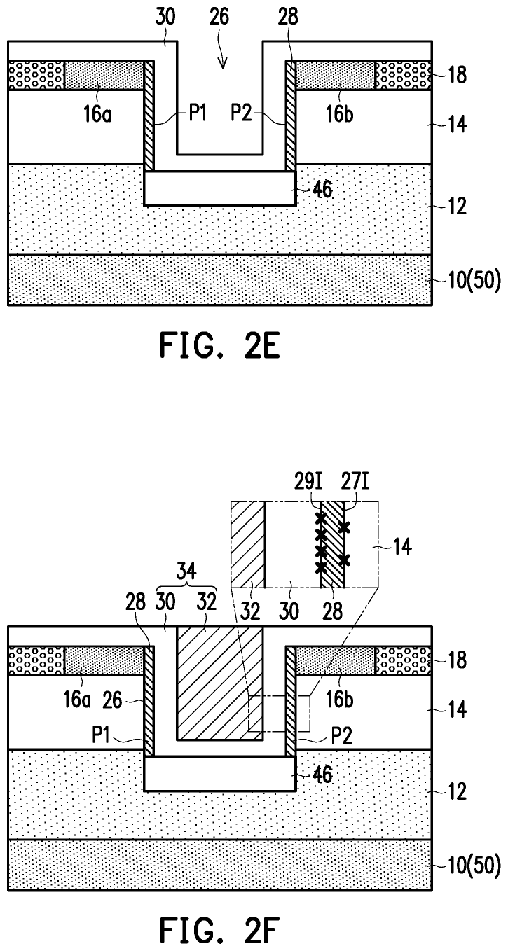

In the semiconductor device 100A, the channel cap layer 28 covers the sidewalls and the bottom surface of the trench 26. However, the disclosure is not limited thereto. In some other embodiments of the disclosure, as shown in FIG. 2G, a semiconductor device 100B is similar to the semiconductor device 100A. However, the channel cap layer 28 of the semiconductor device 100B is divided into a first portion P1 and a second portion P2, and further includes an insulating layer 46. The first portion P1 and the second portion P2 are respectively located on the sidewalls of the trench 26. The insulating layer 46 is disposed at the bottom part of the trench 26 and separates the first portion P1 and the second portion P2. The thickness of the insulating layer 46 is greater than the thickness of the gate dielectric layer 30 of the gate structure. By disposing the insulating layer 46, an electric field effect at the bottom corners of the trench 26 when the semiconductor device 100B is operated could be reduced.

Referring to FIG. 2G, in a process for forming the semiconductor device 100B, except for the insulating layer 46, other materials or components may be formed in a way similar to the process for forming the semiconductor device 100A. FIGS. 2A to 2G are schematic cross-sectional views illustrating a manufacturing process of the semiconductor device 100B according to some other embodiments of the disclosure.

Referring to FIGS. 2A to 2C, the buffer layer 12, the channel layer 14, the first doped region 16a, the second doped region 16b, the third doped region 50, the doped region 18, and the trench 26 are formed according to the above. After the trench 26 is formed, the insulating layer 46 is formed at the bottom part of the trench 26. A process for forming the insulating layer 46 includes forming an insulating material in the trench 26 and on the mask layer 20, then removing the insulating material except for the trench 26 by performing a chemical mechanical polishing process, and then removing the remaining portion of the insulating material in the trench 26 by performing an etching back process. In some embodiments, the top surface of the insulating layer 46 is lower than the bottom surface of the channel layer 14, so as to allow the channel cap layer 28 formed subsequently to completely cover the channel layer 14 on the sidewalls of the trench 26.

Referring to FIG. 2D, the channel cap layer 28 is formed on the sidewalls of the trench 26. The channel cap layer 28 may be formed by performing an epitaxial growth process. Since the bottom part of the trench 26 is covered by the insulating layer 46, and the first doped region 16a, the second doped region 16b, and the doped region 18 are covered by the mask layer 20, the channel cap layer 28 is formed on the sidewalls of the trench 26 without being formed at other positions. The channel cap layer 28 formed on the sidewalls of the trench 26 includes the first portion P1 and the second portion P2 separated by the insulating layer 46.

Referring to FIGS. 2E to 2G, the gate structure 34 and the metal interconnect 42 are formed according to the above. The first portion P1 of the channel cap layer 28 is located between the gate dielectric layer 30 of the gate structure 34 and the channel layer 14, and is located between the gate dielectric layer 30 and the first doped region 16a. The second portion P2 of the channel cap layer 28 is located between the gate dielectric layer 30 of the gate structure 34 and the channel layer 14, and is located between the gate dielectric layer 30 and the second doped region 16b.

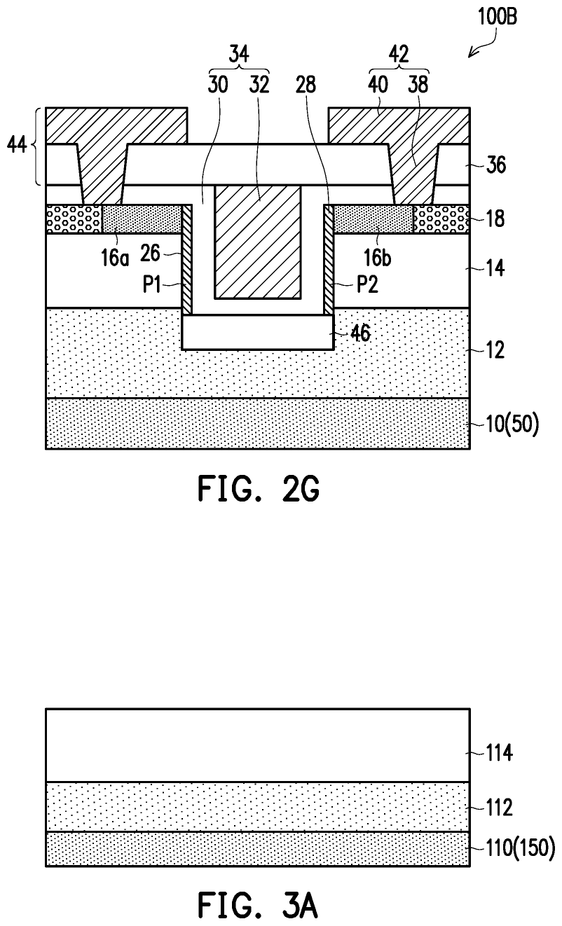

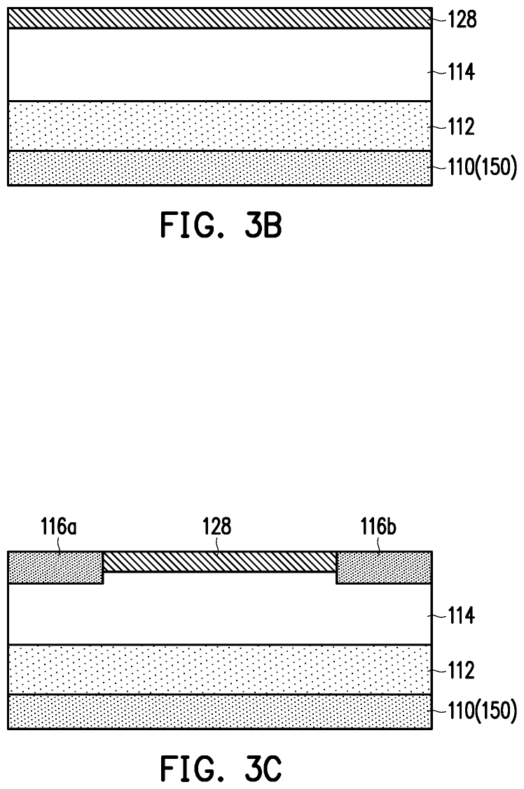

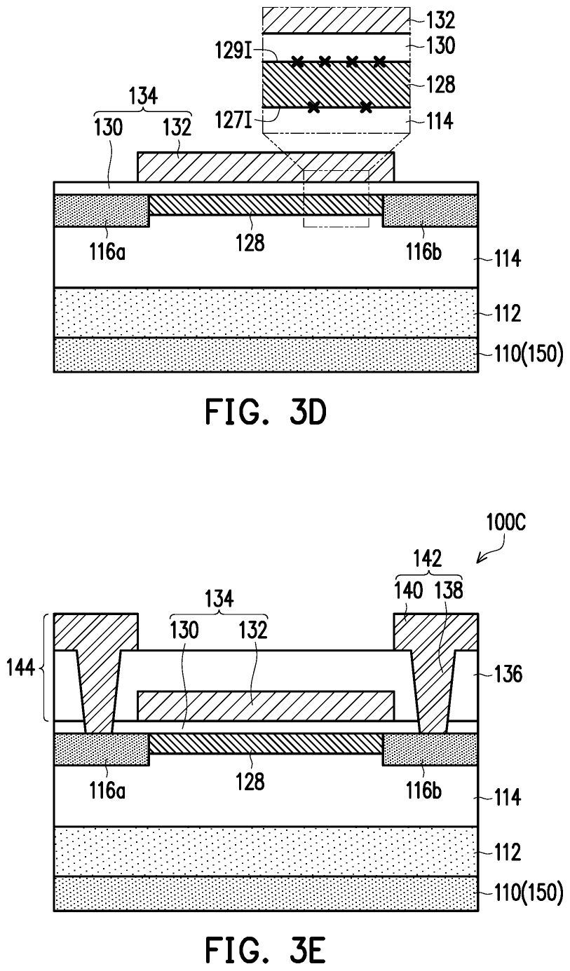

In the semiconductor devices 100A and 100B, the gate structure 34 is buried in the trench 26 of the channel layer 14. Therefore, such devices are referred to as trench-type semiconductor devices or buried-type semiconductor devices. However, the disclosure is not limited thereto. In some other embodiments of the disclosure, as shown in FIG. 3E, a semiconductor device 100C is a plane-type semiconductor device, and a gate structure 134 thereof is formed above the channel layer 114.

Referring to FIG. 3E, the semiconductor device 100C of the disclosure includes a substrate 110, a channel layer 114, the gate structure 134, a first doped region 116a, a second doped region 116b, a third doped region 150, and a channel cap layer 128. In some embodiments, the semiconductor device 100C further includes a buffer layer 112. In some other embodiments, the semiconductor device 100C further includes a metal interconnect structure 144.

The buffer layer 112 and the channel layer 114 are formed on or in the substrate 110. The gate structure 134 is located above the channel layer 114. The first doped region 116a and the second doped region 116b are located in the channel layer 114 on two sides of the gate structure 134. The third doped region 150 is located in the substrate 110 below the channel layer 114. The channel cap layer 128 is located between the gate structure 134 and the channel layer 114. The energy band gap of the channel cap layer 128 is larger than the energy band gap of the channel layer 114. The conductivity type of the dopants of the first doped region 116a, the second doped region 116b, the third doped region 150, and the buffer layer 112 is different from the conductivity type of the dopants in the channel layer 114 and the channel cap layer 128. For example, the first doped region 116a, the second doped region 116b, the third doped region 150, and the buffer layer 112 have dopants of the second conductivity type, and the channel layer 114 and the channel cap layer 128 have dopants of the first conductivity type.

Referring to FIG. 3D, similarly, the channel cap layer 128 is located between the gate dielectric layer 130 and the channel layer 114. Since the difference in lattice constant between the material of the channel layer 114 and the channel cap layer 128 is smaller, the lattice mismatch between the channel layer 114 and the channel cap layer 128 is smaller, and the number of defects of an interface 127I is smaller. The difference in lattice constant between the material of the channel cap layer 128 and the material of the gate dielectric layer 130 is greater. Therefore, the lattice mismatch rate between the channel cap layer 128 and the gate dielectric layer 130 is greater, and the number of defects of the interface 129I is greater.

Moreover, since the energy band gap of the channel cap layer 128 is greater than the energy band gap of the channel layer 114, the majority of carriers flowing out from the first doped region 116a and the second doped region 116b flow to the third doped region 150 via the channel layer 114 with a smaller energy band gap, whereas only a small number of carriers flow via the channel cap layer 128 with a greater energy band gap to the third doped region 150.

Since the carriers are able to avoid the interface 129I with a greater number of defects, the embodiments of the disclosure are able to facilitate carrier mobility and allow the carrier channel to be away from the gate dielectric layer 130 and reduce the chance that a carrier is trapped by a defect of the gate dielectric layer 130. As a result, the characteristic shift of the semiconductor device 100C after operation for a long time could be reduced, and the reliability and the service time of the semiconductor device 100C could be facilitated.

FIGS. 3A to 3E are schematic cross-sectional views illustrating a manufacturing process of a semiconductor device according to still some other embodiments of the disclosure.

Referring to FIG. 3A, the third doped region 150, the buffer layer 112 and the channel layer 114 are formed in accordance with the processes and the materials for the third doped region 150, the buffer layer 112, and the channel layer 114.

Referring to FIG. 3B, the channel cap layer 128 is formed on a surface of the channel layer 114. The material and the process for forming the channel cap layer 128 are the same as or similar to the material and the process for forming the channel cap layer 28.

Referring to FIG. 3C, the first doped region 116a and the second doped region 116b are formed. The first doped region 116a and the second doped region 116b are formed by, for example, forming a mask layer (not shown) on the channel layer 114 by performing a photolithography process, and then performing an ion implantation process. The first doped region 116a and the second doped region 116b have the same conductivity type as the third doped region 150, but have a different conductivity type from the channel cap layer 128. The first doped region 116a and the second doped region 116b sandwich the channel cap layer 128. In some embodiments, the first doped region 116a and the second doped region 116b extend downward from the top surface of the channel cap layer 128 into the channel layer 114. In other words, the bottom surfaces of the first doped region 116a and the second doped region 116b are located at a deeper position closer to the third doped region 150, whereas the bottom surface of the channel cap layer 128 is located at a shallower position away from the third doped region 150.

Referring to FIG. 3D, the gate structure 134 is formed above the channel cap layer 128. The gate structure 134 includes a gate dielectric layer 130 and a gate conductor layer 132. The process for forming the gate dielectric layer 130 and the gate conductor layer 132 include, for example, forming a gate dielectric material and a gate conductor material above the channel cap layer 128 and patterning by performing a photolithography process and an etching process.

Referring to FIG. 3E, the metal interconnect structure 144 is formed above the substrate 110. The metal interconnect structure 144 includes a dielectric layer 136 and a metal interconnect 142. The metal interconnect 142 includes a contact via 138 and a conductive wire 140. The contact via 138 extends and passes through the dielectric layer 136, and is respectively electrically connected with the first doped region 116a and the second doped region 116b. The conductive wire 140 is located on the dielectric layer 136 and electrically connected with the contact via 138. The metal interconnect structure 144 may be formed by adopting any conventional process. Therefore, details in this regard will not be repeated in the following.

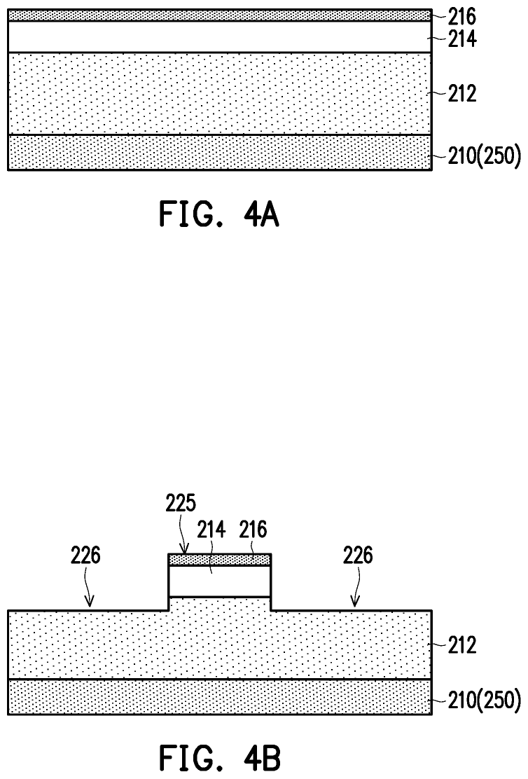

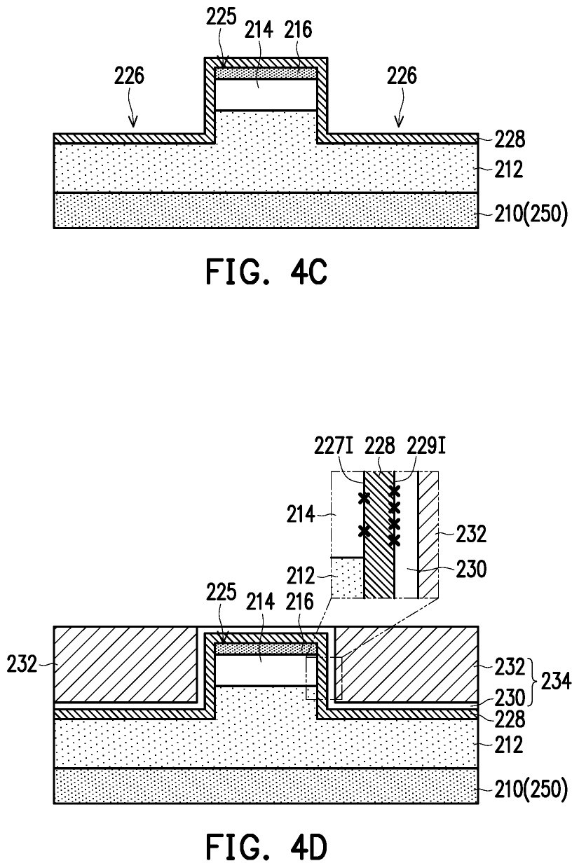

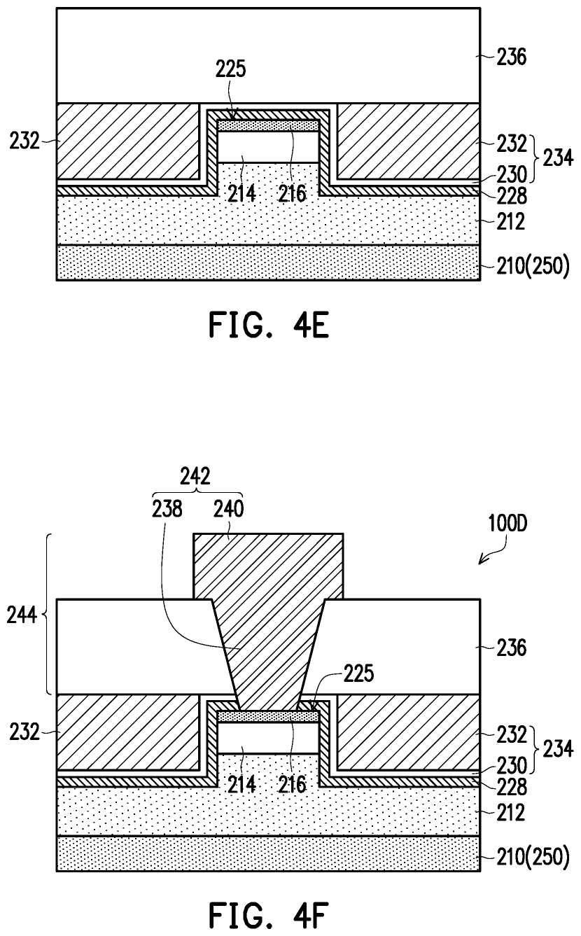

In addition to the semiconductor devices 100A, 100B, and 100C, an embodiment of the disclosure further provides a fin-shaped semiconductor device 100D, as shown in FIG. 4F.

Referring to FIG. 4F, in still some other embodiments of the disclosure, the semiconductor device 100D includes a substrate 210, a fin 225, a channel cap layer 228, a gate structure 234, a channel layer 214, a first doped region 216, and a second doped region 250. In some embodiments, the semiconductor device 100D further includes a buffer layer 212. In some other embodiments, the semiconductor device 100D further includes a metal interconnect 242.

Referring to FIG. 4F, the fin 225 is disposed on the substrate 210 and protrudes from the surface of the substrate 210. The channel cap layer 228 covers the substrate 210 and the top surface and the sidewalls of the fin 225.

The channel layer 214 is located in the fin 225. The buffer layer 212 is located in the fin 225 below the channel layer 214 and the substrate 210. The first doped region 216 is located in the channel layer 214. The second doped region 250 is located in the substrate 210 below the channel layer 214. The gate structure 234 is located on the channel cap layer 228 on the substrate 210. The channel cap layer 228 is located between the gate structure 234 and the first doped region 216, between the gate structure 234 and the channel layer 214, and the gate structure 234 and the buffer layer 212. The energy band gap of the channel cap layer 228 is larger than the energy band gap of the channel layer 214.

Referring to FIG. 4D, similarly, the channel cap layer 228 is located between the gate dielectric layer 230 and the channel layer 214. Since the difference in lattice constant between the material of the channel layer 214 and the material of the channel cap layer 228 is smaller, the lattice mismatch rate between the channel layer 214 and the channel cap layer 228 is smaller, and the number of defects of an interface 227I is smaller. The difference in lattice constant between the material of the channel cap layer 228 and the material of the gate dielectric layer 230 is greater. Therefore, the lattice mismatch rate between the channel cap layer 228 and the gate dielectric layer 230 is greater, and the number of defects of an interface 229I is greater.

Moreover, since the energy band gap of the channel cap layer 228 is greater than the energy band gap of the channel layer 214, the majority of carriers flowing out from the first doped region 216a flow to the second doped region 250 via the channel layer 214 with a smaller energy band gap, whereas only a small number of carriers flow via the channel cap layer 228 with a greater energy band gap to the second doped region 250.

Since the carriers are able to avoid the interface 229I with a greater number of defects, the embodiments of the disclosure are able to facilitate carrier mobility and allow the carrier channel to be away from the gate dielectric layer 230 and reduce the chance that a carrier is trapped by a defect of the gate dielectric layer 230. As a result, the characteristic shift of the semiconductor device 100D after operation for a long time could be reduced, and the reliability and the service time of the semiconductor device 100D could be facilitated.

FIGS. 4A to 4F are schematic cross-sectional views illustrating a manufacturing process of a semiconductor device according to yet some other embodiments of the disclosure.

Referring to FIG. 4A, the second doped region 250, the buffer layer 212 and the channel layer 214 are formed in accordance with the processes and the materials for the second doped region 250, the buffer layer 212, and the channel layer 214. Then, the first doped region 216 is formed in the channel layer 14. The channel layer 214 and the buffer layer 212 have dopants of different conductivity types. The first doped region 216 may be formed by performing an ion implantation process. The first doped region 216, the second doped region 250, and the buffer layer 212 have dopants of the same conductivity type.

Referring to FIG. 4B, the fin 225 is formed by patterning the first doped region 216, the channel layer 214, and the buffer layer 212 by performing a photolithography process and an etching process. A concave part 226 is formed on the periphery of the fin 225. The fin 225 protrudes from the surface of the buffer layer 212 at the concave part 226.

Referring to FIG. 4C, the channel cap layer 228 is formed on the surface of the buffer layer 212 at the concave part 226 and the top surface and the sidewalls of the fin 225. The material and the process for forming the channel cap layer 228 are the same as or similar to the material and the process for forming the channel cap layer 28.

Referring to FIG. 4D, the gate structure 234 is formed above the channel cap layer 228. The gate structure 234 includes a gate dielectric layer 230 and a gate conductor layer 232. The process for forming the gate dielectric layer 230 and the gate conductor layer 232 includes, for example, forming a gate dielectric material and a gate conductor material above the channel cap layer 228 and removing the gate conductor material above the fin 225 by performing an etching back process.

Referring to FIG. 4E, the metal interconnect structure 24 is formed above the substrate 210. The metal interconnect structure 244 includes a dielectric layer 236 and a metal interconnect 242. The metal interconnect 242 includes a contact via 238 and a conductive wire 240. The contact via 238 extends and passes through the dielectric layer 236, and is electrically connected with the first doped region 216. The conductive wire 240 is located on the dielectric layer 236 and electrically connected with the contact via 238. The metal interconnect structure 244 may be formed by adopting any conventional process. Therefore, details in this regard will not be repeated in the following.

The embodiments of the disclosure are able to facilitate carrier mobility and allow the carrier channel to be away from the gate dielectric layer and reduce the chance that a carrier is trapped by a defect of the gate dielectric layer. As a result, the characteristic shift of the semiconductor device after operation for a long time could be reduced, and the reliability and the service time of the semiconductor device could be facilitated.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A semiconductor device, comprising:
a substrate;
a channel layer, located on the substrate, wherein the channel layer has a trench;
a gate structure, disposed in the trench;
a first doped region and a second doped region, disposed in the channel layer on two sides of the gate structure;
a third doped region, located in the substrate below the channel layer; and
a channel cap layer, located between the gate structure and the first doped region, between the gate structure and the second doped region, and between the gate structure and the channel layer,
wherein an energy band gap of the channel cap layer is greater than an energy band gap of the channel layer.

2. A semiconductor device, comprising:
a substrate;
a channel layer, located on the substrate;
a gate structure, disposed above the channel layer;
a first doped region and a second doped region, disposed in the channel layer on two sides of the gate structure;
a third doped region, located in the substrate below the channel layer; and
a channel cap layer, located between the gate structure and the channel layer,
wherein an energy band gap of the channel cap layer is greater than an energy band gap of the channel layer.

3. A semiconductor device, comprising:
a substrate;
a fin, located on the substrate and protruding from a surface of the substrate;
a channel cap layer, covering the substrate and a top surface and sidewalls of the fin;
a gate structure, located on the channel cap layer above the substrate;
a channel layer, located in the fin;
a first doped region, located in the channel layer;
a second doped region, located in the substrate below the channel layer,
wherein the channel cap layer is located between the gate structure and the first doped region and between the gate structure and the channel layer, and
wherein an energy band gap of the channel cap layer is greater than an energy band gap of the channel layer.

4. The semiconductor device as claimed in claim 1, wherein a difference between the energy band gap of the channel cap layer and the energy band gap of the channel layer is less than 1 eV.

5. The semiconductor device as claimed in claim 2, wherein a difference between the energy band gap of the channel cap layer and the energy band gap of the channel layer is less than 1 eV.

6. The semiconductor device as claimed in claim 3, wherein a difference between the energy band gap of the channel cap layer and the energy band gap of the channel layer is less than 1 eV.

7. The semiconductor device as claimed in claim 1, wherein the channel cap layer comprises 6H—SiC, 4H—SiC, 2H—SiC, GaN, AlGaN, AlN, α-Ga₂O₃, diamond, SiGe, Si, or a combination thereof.

8. The semiconductor device as claimed in claim 2, wherein a material of the channel cap layer is the same as a material of the channel layer but has a different crystal phase.

9. The semiconductor device as claimed in claim 8, wherein the channel layer comprises 4H—SiC, and the channel cap layer comprises 2H—SiC.

10. The semiconductor device as claimed in claim 8, wherein the channel layer comprises 6H—SiC, and the channel cap layer comprises 4H—SiC, 2H—SiC, or a combination thereof.

11. The semiconductor device as claimed in claim 8, wherein the channel layer comprises 3C—SiC, and the channel cap layer comprises 6H—SiC, 4H—SiC, 2H—SiC, or a combination thereof.

12. The semiconductor device as claimed in claim 2, wherein a material of the channel cap layer is different from as a material of the channel layer, wherein the channel layer comprises β-Ga₂O₃, the channel cap layer comprises AlₓGa₁₋ₓO, AlGaₓN₁₋ₓ, or a combination thereof, and x is between 0 and 1.

13. The semiconductor device as claimed in claim 1, wherein the channel cap layer and the channel layer are of a same conductivity type, and a doped concentration of the channel cap layer is greater than or equal to a doped concentration of the channel layer.

14. The semiconductor device as claimed in claim 1, wherein a number of defects of an interface between the channel cap layer and a gate dielectric layer of the gate structure is greater than a number of defects of an interface between the channel cap layer and the channel layer.

15. The semiconductor device as claimed in claim 1, wherein a lattice mismatch rate between the channel layer and a gate dielectric layer of the gate structure is greater than 10%.

16. The semiconductor device as claimed in claim 1, wherein a thickness of the channel cap layer is less than 100 nm.

17. The semiconductor device as claimed in claim 2, wherein a thickness of the channel cap layer is less than 100 nm.

18. The semiconductor device as claimed in claim 3, wherein a thickness of the channel cap layer is less than 100 nm.

19. The semiconductor device as claimed in claim 1, further comprising a buffer layer located below the channel layer.

20. The semiconductor device as claimed in claim 1, wherein the channel cap layer comprises a first portion and a second portion respectively located on sidewalls of the trench and separated by an insulating layer disposed at a bottom part of the trench, and a thickness of the insulating layer is greater than a thickness of a gate dielectric layer of the gate structure.
